(19) United States
(12) Patent Application Publication
(10) Pub. No.: US 2020/0279970 A1
(43) Pub. Date: Sep. 3, 2020

(54) Method of Manufacturing a Passivated Solar Cell and Resulting Passivated Solar Cell

(71) Applicant: Tempress IP B.V., Vaassen (NL)

(72) Inventors: Ronald Cornelis Gerard Naber, Apeldoorn (NL); Johannes Reinder Marc Luchies, Waalre (NL); Martijn Lenes, Vaassen (NL)

(21) Appl. No.: 16/476,453

(22) PCT Filed: Feb. 12, 2018
(86) PCT No.: PCT/NL2018/050094

§ 371 Date: Jul. 8, 2019

(30) Foreign Application Priority Data
Feb. 10, 2017 (NL) 2018356

(51) Int. Cl. H01L 31/18; H01L 31/04

(52) U.S. Cl. CPC H01L 31/1868; H01L 31/04; H01L 31/1864; H01L 31/182

(57) ABSTRACT

The method of manufacturing a passivated solar cell comprises the steps of: (1) providing an electrically conductive region at a first side of a semiconductor substrate provided with a textured surface, which comprises dopant atoms of p-type conductivity, and particularly boron; (2) providing a passivation by applying a tunnelling dielectric layer and a polysilicon layer and carrying out an anneal so as to diffuse dopant atoms from the electrically conductive region into the polysilicon layer. A hydrogenated silicon nitride or silicon oxynitride layer may be present on top of the polysilicon layer. The resulting solar cell has a significantly increased lifetime of charge carriers and therewith enhanced open-circuit voltage.

### FIELD OF THE INVENTION

The invention relates to a method of manufacturing a passivated solar cell, comprising the steps of:
providing an electrically conductive region at a first side of a semiconductor substrate;
providing a passivation on the first side.

The invention also relates to a solar cell comprising a semiconductor substrate having a first side and an opposed second side, which first side is provided with a textured surface, wherein an electrically conductive region of p-type conductivity and defining an emitter is present at the first side of the substrate, which first side is covered with a passivation, wherein a tunnelling dielectric and a polysilicon layer are present on the second side of the substrate, which polysilicon layer is doped with n-type dopant, wherein contacts on the second side extend into the polysilicon layer without extending into the semiconductor substrate.

### BACKGROUND OF THE INVENTION

Recently, new types of solar cells with higher efficiency have been commercialized, which are known as a PERT or PERC cell-types. In both cell types, the emitter is present at the first side and is provided with contacts thereto on the first side. At the second, rear side, a contact over the entire surface area or part of the surface area of the solar cell is present. In one further embodiment, a polysilicon layer is present between the rear contact and the substrate. This polysilicon layer is separated from the substrate by means of a tunnel dielectric. In this case, it is not deemed necessary that the rear contact metal extends over the entire rear side, but typically the polysilicon layer does extend over the entire surface of the second, rear side. In certain embodiments, there may also be contacts of opposite polarity on the rear side to form an interdigitated back contact (IBC) structure, such as in the embodiment shown in U.S. Pat. No. 7,468,485.

The use of a polysilicon layer in combination with a tunnel dielectric enhances the efficiency and minority carrier lifetime in the solar cells. The efficiency of solar cells is reduced by the recombination of charge carriers. Such recombination particularly occurs at the surfaces, where the crystal lattice of the semiconductor substrate is disrupted. The tunnel dielectric is effective to limit surface recombination of charge carriers, as the tunnel dielectric and polysilicon stack shields the contacts from the underlying substrate by means of a tunnel dielectric, such as a tunnel oxide. A tunnel oxide is a layer of oxide so thin that the probability of electron direct tunnelling across it is very high; the thickness of a tunnel oxide is less than about 3.0 nm, typically 1-2 nm. The polysilicon defines a contact surface of the contact to a tunnel dielectric. The polysilicon may be annealed after deposition to enhance its crystallinity and/or the size of its crystalline domains. In the late 1980s such structure was invented to make polysilicon emitters for bipolar devices in CMOS technology with phosphorus doped polysilicon, where the introduction of a thin dielectric layer, a tunnel dielectric, served as a very effective charge separation for electrons and holes, thus significantly improving current gain of these transistors. For solar cell devices, a similar structure has been proposed in the 1990s. In U.S. Pat. No. 5,057,439 it is proposed to use polysilicon emitters in solar cells.

Intrinsic polysilicon is not a good conductor. Therefore, a dopant is usually added. When the polysilicon has a large surface area, it may contain domains of different conductivity, such as for instance suggested in U.S. Pat. No. 7,468,485. The n-type dopant is typically phosphorous and the p-type dopant is typically boron, even though other dopants are not excluded. Various methods of doping a material are known. The most common process for doping polysilicon is by means of diffusion. Herein, un-doped, intrinsic polysilicon is deposited. Thereafter a dopant is deposited in a manner to result in a silicate glass, typically borosilicate glass (BSG) or phosphosilicate glass (PSG). Subsequently, an anneal is done for instance at 950° C. during 1 hour. As a result hereof, the dopant diffuses into the polysilicon, which results in a sufficiently high conductivity. After this anneal, the polysilicon is contacted with the metallization. A suitable metallization scheme needs to be incorporated as known per se to the person skilled in the art.

In this type of solar cells, where the metallization is indirectly connected to the substrate, by means of a tunnel dielectric, the contacts are herewith ‘passivated’, meaning that much less of the cell current can recombine at the contacts. These contacts are therefore also referred to as ‘passivated contacts’.

As shown in U.S. Pat. No. 7,468,485, the first side of the substrate may be provided with a tunnel dielectric and a polysilicon layer as well. The tunnel dielectric is applied in a thickness of about 1 nm using ozone, and the polysilicon layer is applied in a thickness of 20 nm using atmospheric pressure chemical vapour deposition (APCVD). This APCVD process is used to apply the tunnel dielectric and the polysilicon layer in a single-sided manner. Therewith, the layer stack of tunnel dielectric and polysilicon on the second side is applied and provided with dopant sources before the application of the tunnel dielectric and the polysilicon layer on the first side. Although the sequence of single-sided processes appears adequate, APCVD has significant disadvantages. First of all, the effective deposition process is slow, also because the solar cells are not to be arranged in wafer boats such as in LPCVD or PECVD, but in a planar arrangement. Secondly, the layers are not deposited defect-free, but rather with pinholes. When creating tunnel dielectrics so as to define passivated contacts, the presence of pinholes easily degrades the passivation quality. This is the reason to apply the tunnel oxide by means of ozone. However, the ozone treatment requires processing in a separate reactor, which is not efficient either. It would be better for efficiency to create a process based on more efficient chemical vapour deposition processes, such as PECVD and particularly LPCVD.

Moreover, in the process of U.S. Pat. No. 7,468,485, the polysilicon layer on the first side is n-type doped. This occurs by application of a doping layer on top of the polysilicon layer, which is subsequently removed again. In this process, the n-doped polysilicon layer replaces the emitter that is conventionally applied into the semiconductor substrate, as specified in column 2, lines 29-31. This process is not deemed optimal, and particularly not for p-type doping on the first side. First of all, the removal of a doping layer, typically a glass, over a 20 nm thick polysilicon layer tends to lead to non-uniformity in the thickness of the polysilicon layer and/or other damage such as strong in-diffusion of dopant from the glass into the polysilicon and past the tunnel oxide into the substrate due to thickness non-uniformity. Furthermore, the glass formation and removal tends to remove 10-20 nm of polysilicon, which creates a big problem if one wants to end up with a thin layer of 20 nm with a uniform thickness. Since the first side is intended for capturing radiation, such damage will reduce the optical transmission of the incoming radiation, and therewith in a reduction of the efficiency of the solar cell. Furthermore, boron-type doping of a polysilicon layer is known to be difficult to make uniformly. The doping tends to move to the interface with the tunnel dielectric and/or grain boundaries. This makes in situ doping of the polysilicon layer during its deposition rather problematic, unless using specific deposition processes such as described in applicant's non-prepublished application PCT/NL2016/50665.

More recently, further examples of passivated solar cells with a polysilicon layers on both the first side and the second side have been published, for instance R Peibst et al, 32th European Photovoltaic Solar Energy Conference, 22 Jul. 2016, and M. K. Stodolny et al, Solar Energy Materials & Solar Cells, 153 (2016), 24-28. Peibst et al. reports a decrease in the thickness of the polysilicon layers to values of 20 nm, as desired for optical transparency. As a consequence, the paper indicates the need for deposition of a transparent conductive oxide to obtain additional lateral conductivity. On top thereof, a silicon nitride layer is provided as a capping layer. The polysilicon layer was either ex-situ doped with ion implantation, or in situ. In the latter process, the tunnel dielectric is applied as a wet chemical oxide. It will grow in an anneal step of the polysilicon layer. A resulting cross-sectional drawing is shown as a target cell structure by Peibst et al. However, neither is specified with which process option this target structure is to be made, nor is any indication given that the target structure was indeed realized.

It is therefore desired to provide a further process for the provision of a p-type doped polysilicon layer on the first side of a substrate of a solar cell, wherein there is particularly no need to remove layers on top of the polysilicon layer.

### SUMMARY OF THE INVENTION

It is therefore a first object of the invention to provide an improved process of the type specified in the opening paragraph, so as to provide a p-type doped polysilicon at the first side of the substrate. It is a further object of the invention to provide a solar cell therewith.

According to a first aspect, the invention thereto provides a method of manufacturing a passivated solar cell, comprising the steps of providing an electrically conductive region at a first side of a semiconductor substrate and providing a passivation on the first side, wherein the electrically conductive region comprises dopant atoms of p-type conductivity. The passivation is provided by applying a tunnelling dielectric layer and a polysilicon layer and carrying out an anneal so as to diffuse dopant atoms from the electrically conductive region into the polysilicon layer. According to a second aspect, the invention relates to a solar cell comprising a semiconductor substrate having a first side and an opposed second side, which first side is provided with a textured surface, wherein an electrically conductive region of p-type conductivity and defining an emitter is present at the first side of the substrate, which first side is covered with a passivation, wherein a tunnelling dielectric and a polysilicon layer are present on the second side of the substrate, which polysilicon layer is doped with n-type dopant, wherein contacts on the second side extend into the polysilicon layer without extending into the semiconductor substrate, wherein the passivation on the first side comprises a tunnel dielectric and a polysilicon layer doped with p-type dopant.

The invention uses a passivation comprising a tunnel dielectric and a p-type doped polysilicon layer on top of a p-type emitter. It is based on autodoping of the polysilicon layer by means of dopant atoms originating from the emitter, i.e. the electrically conductive region on the other side of the tunnel dielectric (preferably a tunnel oxide). Such autodoping is found to be effective to doping of the polysilicon layer with p-type dopant, more particularly boron dopant, without the need for the application of any further doping layer on top of the polysilicon layer. The resulting concentration of boron dopant in the polysilicon is effective to allow application of contacts.

Furthermore, in comparative experiments to a solar cell having a passivation including a thermal oxide on the first side, the passivation comprising the tunnel dielectric and the p-type doped polysilicon layer was found to have an increased open-circuit voltage V_{oc}. This open-circuit voltage is a measure for the tendency of recombination at the surface: the higher the V_{oc}, the less recombination will occur. Such an increase in the open circuit voltage V_{oc} was not expected, as the autodoping process through the tunnel dielectric would be expected to adversely affect the passivation properties of the tunnel dielectric, such that there would no longer be any passivated contact. This expectation is supported by comparative experiments with a boron doped polysilicon layer overlying a tunnel oxide and a silicon substrate. Boron diffusion through the tunnel oxide was herein found to be detrimental for the passivation of the solar cell.

Particularly, in accordance with a preferred embodiment of the invention, the emitter has a resistance of at most 300 ohm/square, by further preference at most 200 ohm/square, such as 100-170 ohm/square. Such resistance was found optimal for an optimized emitter. Simultaneously, this corresponds to a doping concentration that may diffuse through the tunnel dielectric in an anneal, in a manner so as to achieve appropriate doping of the polysilicon layer.

In one embodiment, the emitter arranged to be laterally continuous. In another embodiment, the emitter is patterned, and more particularly in accordance to a pattern that substantially corresponds with any contact area in the polysilicon layer. The contact area is in one implementation defined by means of metal contacts, which in accordance with the solar cell of the invention, do extend into the polysilicon layer, but not through the polysilicon layer. In another implementation, such contact area is defined in that the polysilicon layer is patterned, i.e. arranged according to a pattern, so that the layer is laterally not continuous, or that the polysilicon layer has a larger thickness in the contact areas than outside the contact areas. A preferred pattern for the contact area is a fingered pattern. Such a pattern comprises a plurality of elongated bars that are mutually connected by a cross-bar. The emitter area could be a variation of the contact area, for instance in that merely a plurality of elongated bars is present, and/or that the extension of such elongated bars is different so as to optimize the charge emission from the emitter into the substrate.

In one suitable embodiment, a hydrogenated nitride layer or oxynitride layer is applied on top of the polysilicon layer. This hydrogenated silicon nitride layer is suitably deposited at a temperature giving rise to migration of the hydrogen into the underlying polysilicon layer. This hydrogen migration is believed to improve the integrity of the tunnel oxide. Rather than a higher deposition temperature, a separate anneal may be carried out. When using plasma enhanced chemical vapour deposition (PECVD) for the deposition of the nitride or oxynitride layer, the preferred temperature range is for instance from 300 to 600° C., preferably from about 400° C. to about 500° C. The use of a silicon nitride layer is preferred. Alternatively, use could be made of titanium nitride or the like. It is not excluded that an alternative hydrogen source than a hydrogenated silicon nitride layer is applied for achieving hydrogen migration into the polysilicon layer and possibly the tunnel oxide.

In a further embodiment of the method, the electrically conductive region in the substrate is applied by diffusion of boron into the semiconductor substrate using a heat treatment. The boron is for instance applied as a boron tribromide, which forms a boron silicate glass on top of the semiconductor substrate. This is thereafter diffused into the semiconductor substrate by means of a heat treatment. Where the boron tribromide is initially applied on both sides of the semiconductor substrate, the electrically conductive region in the substrate at second side is suitably removed prior to application of the tunnel dielectric and the polysilicon layer. Thus, in the process of the invention, the p-type dopant undergoes at least twice a heat treatment. The first heat treatment results in diffusion of the boron dopant from the dopant source into the substrate. Surprisingly, the second heat treatment is feasible of diffusing part of the boron dopant back out of the substrate through a tunnel oxide into a polysilicon layer that has been applied after the first heat treatment. Typically, such a heat treatment to achieve boron diffusion is carried out at a temperature of at least 700° C. and during a period of for instance 30-120 minutes. Typically, the temperature of the heat treatments is in the range of 700-1100° C., more preferably at least 800° C., and even more preferably at least 900° C. during at least 10 and preferably at least 30 minutes.

The second heat treatment needed to diffuse p-type dopant atoms from the electrically conductive region into the polysilicon layer is most suitably combined with a heat treatment for diffusion of n-type charge carriers into a polysilicon layer deposited at the second side of the substrate. It is observed that the necessary thermal budget for the diffusion of p-type dopant atoms, more particularly boron atoms, through the tunnel dielectric is higher than that needed for the diffusion of n-type dopant, for instance after doping by means of ion implantation. Thus at conventional conditions for n-type dopant diffusion, the diffusion according to the invention of boron from the boron emitter through the tunnel dielectric into the polysilicon layer will not occur. Surprisingly, at conditions suitable for p-type dopant diffusion, diffusion of the n-type dopant on the second side does not lead to significant leakage of dopant into the substrate or creation of non-uniformity in the doping level. The leakage of n-type dopant, more particularly phosphorous into the substrate seems further inhibited, in a preferred embodiment, by the presence of an etch stop intermediate layer within the polysilicon layer at the second side that is doped with n-type dopant.

In one preferred embodiment, the tunnelling dielectric and the polysilicon layer are applied on the first side and on the second side. More preferably, the polysilicon layer of the first side is thinned back prior to the anneal step, so that the polysilicon layer on the first side is thinner than the polysilicon layer on the second side. A reduction in the thickness of the polysilicon layer on the first side, for instance to a thickness of less than 50 nm, for instance 5-30 nm, is desired in view of the optical transmission. A corresponding reduction is not preferred on the second side in order to enable sufficient lateral conductivity. The polysilicon layer itself is suitably applied by means of low-pressure chemical vapour deposition (LPCVD).

Thus, in a preferred embodiment, said polysilicon layer in the passivation on the first side has a smaller thickness than the polysilicon layer on the second side. With the expression “polysilicon layer in the passivation” reference is made to those areas on the first side that actually function as a passivation to reduce recombination of charge carriers. At the location of any contacts, this typically does not apply. In other words, in one suitable embodiment, contact areas are defined on the first side, wherein the polysilicon layer has a larger thickness than in the passivation, i.e. in the area on the first side devoid of contacts are configured for capturing radiation.

However, in an alternative embodiment, the polysilicon layers on the first side and on the second side may be present in a thickness that is at least substantially equal. In this alternative embodiment, the polysilicon layers are suitably doped after the deposition. Suitably, a metallisation is applied on the polysilicon layer on the second side, so as to enhance the lateral conductivity thereof.

As indicated before, the polysilicon layer at the second rear side is preferably and at least partially doped with an n-type dopant such as phosphorous. This implies that even though the polysilicon layers on the first and on the second side are formed simultaneously, nevertheless opposed doping is being applied.

In a first embodiment, thereto use is made of doping of the polysilicon layer, also at the second side, after its deposition. The dopant can be applied to the second rear side in any known manner, such as by means of coating (spray, spinning) or printing a doping layer, by vapour deposition of a doping source such as phosphorus oxychloride (POCl3) that reacts with the polysilicon layer to form a phosphosilicate glass and by implantation, plasma implantation doping or otherwise, as known per se. When such doping necessarily arrives on both sides of the substrate, such as by application from a vapour source, the first side would typically be masked prior to the provision of the dopant layer, for instance with a masking layer. However, it is preferred to apply the dopant in a directional manner merely or substantially on the second side only, for instance by means of ion implantation, more particularly with directional ion beams. This has the advantage, among others, that separate isolation of the edges of the substrate, such as by means of a laser or plasma, is not needed.

In a second embodiment, n-type doping is applied into the polysilicon layer, during deposition of the polysilicon layer. Preferably, n-type doping of the polysilicon layer is applied during the deposition of the polysilicon layers, such that a first sublayer of the polysilicon layer has a lower concentration of n-type doping than a second sublayer, and wherein said second sublayer is removed from the first side after the deposition. The increase in dopant concentration with increasing distance to the tunnelling dielectric allows removal of the major portion of n-type doping from the first side by single sided thinning back of the polysilicon layer. Clearly, a capping layer may be applied on the second side so as to achieve single sided etching. Such capping layer may for instance be in the form of a coating material. Furthermore, the capping layer may be provided in a patterned manner, if thickness variations of the polysilicon layer on the second side are desired. The provision of the capping layer in a patterned manner may for instance be in the form of printing, such as ink jet printing or screen printing and/or as a photolithographical mask. When the dopant concentration of n-type doping in the first sublayer of the polysilicon layer is larger than zero, this may be compensated by the subsequent autodiffusion of the p-type dopant.

Several implementations are feasible for the deposition of the polysilicon layer with a varying doping profile. For instance the first sublayer may be substantially undoped, while the doping concentration increases within the second sublayer. Alternatively, the doping concentration may be comparatively low in the first sublayer and close to the interface with the tunnelling dielectric and then increase gradually or stepwise, up to reaching a maximum doping concentration anywhere in the second sublayer. It is even not excluded that the polysilicon layer is doped during deposition using both n-type and p-type dopant. The doping concentration of the n-type dopant would increase with the distance to the tunnelling dielectric, gradually, stepwise or as a combination thereof, and suitably starting with a zero concentration. The doping concentration of the p-type dopant would decrease or be constant during deposition and typically start with a concentration above zero.

In one preferred implementation, the first and the second sublayer are mutually separated by means of an intermediate layer. Herein, the doping profile may be as discussed above. Preferred options for the doping of the first sublayer are undoped or (lightly) p-type doped. Suitably, such an intermediate layer is a further dielectric. More particularly, it is a layer that can be applied in the same reactor wherein the polysilicon layer is formed. This reactor is more preferably a low-pressure chemical vapour deposition apparatus (LPCVD), which leads to regular, conformal layers of polysilicon. Other types of chemical vapour deposition (CVD) such as atmospheric pressure (CVD), plasma enhanced chemical vapour deposition (PECVD) are however not excluded. More preferably, the said intermediate layer may be formed at a temperature equal to or similar to the temperature at which the polysilicon is formed. This minimizes loss of process time in the reactor due to the need of heating and cooling the reactor before and after (or after and before) the application of the intermediate layer. The intermediate layer is for instance a thermal oxide, another silicon oxide (for instance based on tetraoxyorthosilicate (TEOS), silane or dichlorosilane) or a layer with a different doping profile. This intermediate layer is subsequently used as an etch stop during the removal of a portion of the polysilicon layer. More preferably, in case that the intermediate layer is a thermal oxide, the thickness of the first sublayer is at most 20 nm, and/or the thermal oxide is applied so as to be open (included pinholes), for instance with a thickness of less than 3 nm, more particularly less than 2 nm or even at most 1 nm. A closed layer limits the migration of the n-type dopant, such that the effective distance between the substrate and the n-type dopant layer becomes larger. This appears less preferred. It has been found experimentally that an intermediate thermal oxide works effectively as an etch stop, but does not hinder the diffusion of n-type dopant through the polysilicon layer at the second side.

Suitably, the process is optimized such that the polysilicon layer on the second side has a thickness of 50-300 nm, for instance 70-200 nm, more preferably 80-150 nm, for instance 100-120 nm. The polysilicon layer on the first side suitably has a thickness of less than 50 nm and more preferably in the range of 5-30 nm, for instance 10-20 nm. The dopant concentration of the polysilicon layer on the second side is suitably in the range of 0.7-10.10²⁰/cm³, preferably 1-5.10²⁰/cm³. The dopant concentration of the p-type dopant on the first side is comparatively low, for instance 1-7.10¹⁹/cm³, for instance 4-6.10¹⁹/cm³. The tunnel dielectric is more preferably a tunnel oxide with a thickness of at most 3 nm, and preferably in the range of 0.8-2 nm, for instance 1.2-1.7 nm. The emitter is suitably created so as to have a sheet resistance in the range of 60-120Ω/□.

In again a further embodiment, at least one contact is applied onto the first side into the polysilicon layer without extending to the underlying substrate. In one embodiment, such contact is applied using a metal paste with a paste composition such that it etches through any dielectric layer. Such paste is known per se. For a p-type layer, a paste on the basis of silver (Ag) or aluminium-silver (AlAg) is deemed suitable. Alternatively, use can be made of deposition by means of electro plating. A suitable implementation hereof is the application of nickel that is in contact with the polysilicon layer, optionally extended with silver. Alternatively, the nickel layer can be followed by a copper layer with a suitable cover layer, but also other metal stacks can be envisioned.

Particularly in the embodiment that makes use of a paste, it is deemed preferable that the polysilicon layer on the first side is provided with a first area that substantially corresponding to a location of the at least one contact, in which first area the polysilicon layer is provided with a larger thickness than in the passivation (area). Providing a larger thickness at the first area where the at least one contact is to be applied provides a larger tolerance for the application of the metal paste as to prevent metal penetration past the tunnelling layer. The metal paste is typically applied by means of screen printing and then undergoes a fast fire-through contacting process. The achieved depth of such fire-through contacts tends to vary across the surface of the solar cell so a certain thickness is required for the polysilicon layer in order to provide a proper tolerance. Such variation is furthermore enhanced through the texture of the surface on the first side of the substrate. The thickness variation is suitably applied to the polysilicon layer. This may be achieved, for instance, by etching through a masking layer, during the front side polysilicon etching.

According to a further aspect of the invention, a method of manufacturing a passivated solar cell is provided. Said method comprises the steps of: (1) providing a semiconductor substrate with a first and a second opposed side; (2) providing a tunnel dielectric and a polysilicon layer onto the second side and onto the first side, wherein the tunnel dielectrics and the polysilicon layers on the first and the second side are simultaneously formed. Herein, an etch stop interface is created within the polysilicon layer on the first side, and the polysilicon layer on the first side is thinned up to the etch stop interface. Preferably, the etch stop interface is defined within the polysilicon layer both on the first side and on the second side.

According to again a further aspect of the invention, a solar cell is provided comprising a semiconductor substrate having a first side and an opposed second side, on which first side and which second side a tunnelling dielectric and a polysilicon layer are present, wherein at least the polysilicon layer on the second side is at least partially doped with n-type dopant, wherein the polysilicon layer on the second side has a larger thickness than the polysilicon layer on the first side. Herein the polysilicon layer on the second side comprises a first sublayer of dielectric material between a second and a third sublayer of polysilicon.

It has been observed by the inventors in investigations leading to the present invention, that polysilicon layers with different thicknesses can be created on the first and the second side by incorporating an etch stop interface within the polysilicon layer that is applied simultaneously on the first and the second side. It has moreover been found that creation and use of such etch stop interface is feasible without being detrimental for the distribution of dopant within the polysilicon layer on the second side. Such a distribution of dopant up to the interface between the polysilicon layer and the tunnel dielectric is desired so as to enable application of a contact with sufficiently low resistance, wherein the contact extends into the polysilicon layer without extending to the semiconductor substrate.

A preferred etch stop interface, which remains detectable in the resulting solar cell is an intermediate dielectric layer present between a first and a second sublayer of polysilicon. More particularly the intermediate dielectric layer, such as an oxide or an oxynitride, is applied in a thickness that is sufficiently thin, for instance up to 3 nm, and more preferably even up to 2 nm or at most 1 nm. Rather than a thermal oxide, the intermediate dielectric layer can be prepared by deposition of silicon nitride or silicon oxynitride, or by deposition of a different oxide, for instance by means of tetraethoxyorthosilane (TEOS) or a combination of dichlorosilane and nitrous oxide (N2O). Furthermore, the deposition temperature may be adjusted so as to create a layer that is less dense and therefore less a barrier to diffusion of dopant atoms, such as phosphorus atoms. Preferably, the first and the second sublayer of polysilicon and the intermediate dielectric layer are all deposited in a single reaction chamber by means of low-pressure chemical vapour deposition (LPCVD). This is beneficial for processing and limits unexpected contamination and/or damage of the thin layers.

Alternatively, use can be made of an etch stop interface in the form of a transition between a first sublayer and a second sublayer of polysilicon, wherein the first sublayer has a first composition and the second sublayer has a second composition. More particularly, the first and second sublayer differ with respect to the doping type and/or doping concentration. For instance, the second sublayer is n-type doped, such as with phosphorus, and preferably in situ n-type doped, and the first sublayer is p-type doped such as with boron. According to an alternative implementation, the first sublayer is in situ p-type doped and the second sublayer is undoped.

Additionally or alternatively, the sublayers may also differ in the grade of crystallinity, or other physical parameters. A suitable etchant that is sufficiently selective between n- and p-type doped silicon is for instance ethylenediamine, more generally, an amine or diamine etchant. However, alternative etchants, which contain hydroxide are however not excluded and generally deemed advantageous. Examples thereof include sodium hydroxide (NaOH), potassium hydroxide (KOH) and tetramethylammonium hydroxide (TMAH), and/or combinations thereof and aqueous solutions thereof. Typically, such hydroxide based etchants are applied as 20-40 wt % solutions. An alcohol such as isopropyl alcohol may be added into the solution.

In the context of the present invention, it is deemed preferable that a first sublayer is relatively thin, for instance less than 20 nm. The first sublayer is applied without doping in a first implementation. In an alternative implementation, the first sublayer may be applied with in-situ doping of p-type dopant, more particularly boron. Therewith the overall dopant concentration in the polysilicon layer may be increased. Alternatively, the anneal may be carried out with a limited thermal budget, for instance up to a level that merely limited boron diffusion through the tunnel dielectric occurs or even without any boron diffusion through the tunnel dielectric.

Advantageously, a second sublayer is applied in a larger thickness, for instance up to 200 nm, for instance 50-120 nm. In a first implementation, the second sublayer is applied without doping. This simplifies formation of the second sublayer of the polysilicon layer. The doping of the second sublayer and the underlying first sublayer is then applied separately, for instance by means of ion implantation but alternatively by application of a dopant source in any known manner. In a second implementation, the second sublayer is applied with doping, i.e. in situ doped. This doping may be suitable to compensate any p-type dopant applied in the first sublayer. Furthermore, the doping will reduce the level of doping after deposition. Particularly in case of doping by means of ion implantation, this will increase throughput through the ion implanting apparatus. If the second sublayer is in situ doped, it is not necessary that the dopant concentration is constant throughout the second sublayer. It is for instance feasible that a first portion closer to the first sublayer is provided with a higher dopant concentration, so as to ensure a sufficiently high dopant concentration at the interface with the tunnelling dielectric and/or to compensate any p-type dopant present in the first sublayer.

In a further embodiment, the thinning of the polysilicon layer on the first side, particularly by means of wet-chemical etching is preceded by means of an etch resistance enhancement treatment of the polysilicon layer on the second side. Such treatment results in enhancement of the etch resistance of the polysilicon layer on the second side. Therewith it is achieved that polysilicon material on the first side is selectively removed relative to polysilicon material on the second side, without the need for one-sided etching. A preferred etch resistance enhancement treatment is amorphising at least a surface of the polysilicon layer on the second side, for instance amorphisation of at least part of the polysilicon layer on the second side. Such amorphisation may be achieved by means of ion implantation, preferably with directional ion beams, into the polysilicon layer on the second side.

More preferably, the amorphising of at least a surface of the polysilicon layer is carried out by ion implantation of dopant into the polysilicon layer on the second side, said ion implantation simultaneously embodying a step of applying dopant to the polysilicon layer on the second side. It has been found that implantation of phosphorous is advantageous, and efficacious for polysilicon doping with n-type dopant. The phosphorus may be implanted into an upper portion of the polysilicon layer and/or also into deeper portions (i.e. more closer to the tunnel dielectric). Such implantation may serve to weaken any intermediate dielectric layer inside the polysilicon layer. Thus, the implantation serves both as an etch resistance enhancement treatment and as introduction of dopant. Nevertheless, it is not excluded that one or more sublayers of the polysilicon are also doped by means of an in-situ doping process during chemical vapour deposition, as known per se to the skilled person.

While the amorphisation, particularly by means of ion implantation, is carried out maskless in a first, preferred implementation, it is not excluded that the amorphisation is carried out according to a predefined pattern. The amorphisation according to a predefined pattern allows removal of a second sublayer of the polysilicon layer both from the first side and from the non-amorphized portions of the polysilicon layer on the second side. Subsequently, p-type doped portions may be created in the second side between remaining amorphized portions of the n-type doped polysilicon layer. Resulting alternating n-type doped polysilicon and p-type doped portions can be used for creating alternatingly arranged contacts, for instance in the form of interdigitated back contacts. The p-type doped portions could be created by deposition of a p-type dopant source, such as proposed in U.S. Pat. No. 7,468,485, by means of one-sided chemical vapour deposition or by means of deposition in liquid form. Rather than merely a dopant source, creation may further involve deposition of silicon, for instance amorphous silicon or polysilicon. In again a further implementation, no further dopant would be applied onto the remaining first sublayer. This is most suitable, if a first sublayer of the polysilicon layer has been in situ doped with p-type dopant. Alternatively, or additionally, a specific electrically conductive material, such as a conductive oxide is applied, particularly in a patterned manner onto the exposed portions of the first sublayer of the polysilicon layer on the second side.

Alternatively, the etch resistance enhancement treatment may involve deposition of a mask layer, particularly on the second side. The mask layer on the second side may be patterned or non-patterned (continuous). Suitably, use is made of a material which is able to withstand a subsequent anneal. In one implementation, use is made of a hyperstoichiometric oxide, and/or an oxide having lower density and/or a hygroscopic oxide. Such an oxide may be converted into a thermal oxide in a subsequent anneal step. Examples of materials are SiO₂₊ₓ:H, phosphosilicate glass, TEOS-based oxide. Such layers may be applied single-sided, even by means of coating, spinning or printing, optionally with a subsequent heat treatment at temperature up to 400° C. Still, there is no need to remove the mask layer separately after the etching. In another embodiment, the mask layer is a silicon nitride or silicon oxynitride.

Suitably, the method further comprises the steps of applying a dopant to the polysilicon layer on the second side, and diffusing the dopant into the polysilicon layer on the second side by means of an appeal. These steps constitute a common way of applying dopant into the polysilicon layer. Preferably, the anneal step is carried out after thinning of the polysilicon layer on the first side. Thus, if any dopant would also diffuse on the first side, this dopant is removed. The dopant is preferably applied by means of ion implantation, though a diffusion technique as known per se could be applied alternatively or even additionally. The latter has however the disadvantage a dopant layer will be present on top of the polysilicon, typically on two sides. This has to be removed again and it may be difficult to control the etching process carefully.

In one further embodiment, dopant is also applied into the polysilicon layer on the first side. In order to achieve this, various techniques are feasible. A preferred way of doping is the application of an electrically conductive region of p-type dopant at the first side of the semiconductor substrate prior to the provision of the tunnel dielectrics and polysilicon layers. The anneal is then carried out so as to achieve diffusion of p-type dopant through the tunnel dielectric into the polysilicon layer on the first side. Alternatively, the first layer could be in situ doped, for instance by alternating application of polysilicon and boron sublayers.

In one again further embodiment, both n-type dopant and p-type dopant are applied into the polysilicon layer on the second side. This situation for instance arrives due to in situ doping of both the first and the second sublayer. If the total amount of doping of the second sublayer exceeds that of the first sublayer, the first type doping (p-type) will not have a negative effect.

Suitably, the first and the second sublayer in the resulting solar cell have a dopant concentration that is substantially uniform.

While it is preferred in the context of the invention, that the substrate will be n-type doped, the method for selective creation of polysilicon layers of different thickness on the first and the second side is applied in combination with a p-type doped substrate in an alternative embodiment. While it is preferred in the context of the invention, that an emitter is defined in the substrate at the first side of substrate, the method of selective creation of polysilicon layers of different thickness on the first and the second side, may also be applied without emitter in the substrate. For instance, when a p-type substrate is used, an n-type emitter could be applied in the polysilicon layer on the first side, which is for instance in-situ doped, and/or doped by means of ion implantation or plasma ion implantation. Also, in case of a n-type substrate, a p-type doped polysilicon layer could be used as an emitter, more particularly with interdigitated contacts at the second side. It is furthermore preferred that the first side is provided with a textured surface.

In again a further embodiment, the method further comprises the step of providing an anti-reflection coating onto the first side. This embodiment is common and is deemed beneficial for increasing light absorption, as well as for protection of the comparatively thin polysilicon layer on the first side. Preferably, the antireflection coating is a hydrogenated silicon nitride or silicon oxynitride layer. Migration of hydrogen is effected from the antireflection coating into the thinned polysilicon layer and optionally the underlying tunnel dielectric. This improves the passivation performance. Furthermore, it is deemed suitable that a silicon nitride or silicon oxynitride layer is applied both on the first side and the second side. In the context of the invention, it is suitable to apply metallisation on the second side and optionally also on the first side in known manner. Preferred application methods are described elsewhere in this application.

In again a further embodiment to achieve contacts of both (n+ and p+) polarities on the second side of the substrate, the electrically conductive region defined by means of boron diffusion from a borosilicate glass may be retained at first areas on the second side. Thereafter, polysilicon layers may be provided on the first side and on the second side. N-type dopant, such as phosphorus is thereafter applied at second areas on the second side, which are different from the first areas. The application of phosphorus is suitably carried out by implantation, although an alternative method for local application of a dopant source is not excluded. Portions of the polysilicon layer on the second side, and on the first side, that remain undoped, are thereafter selectively etched away, using the amorphisation for etch selectivity and/or by applying an etch mask. A subsequent anneal of sufficient temperature will result in diffusion of the boron dopant in the first areas of the substrate adjacent to the second side into the polysilicon layer through the tunnel oxide. Furthermore, the phosphorus will be distributed through the second areas in the polysilicon layer. As a result, a polysilicon layer on the second side is created with selective p-doped first areas and n-doped second areas. Contacts can thereafter be applied to the said first and second areas. If the contacts on the first areas would go through the passivation layer into the substrate, that may not be perfect. However, since the emitter extends locally, it will not harm operation of the solar cell.

In an even further implementation of said embodiment of having a p-type emitter in the substrate and the polysilicon in first areas and a n-type doping in the polysilicon and optionally the substrate in second areas, it is not necessary that an electrically conductive region (emitter) is present in the substrate at the first side. As such, it is not necessary either that the polysilicon layer on the first side is doped at all, i.e. by diffusion of boron dopant from the substrate into the polysilicon layer. Furthermore, such a configuration with an undoped polysilicon layer on the first side may be applied both with a n-type substrate and a p-type substrate. In the case of a p-type substrate, then it may be most suitable, that to apply boron dopant by diffusion in the manner described above, and to form the emitter by means of diffusion of the phosphorus doping from the polysilicon layer into the substrate.

While it is preferred in the context of the invention that an electrically conductive region in the substrate at the first side extends continuously, i.e. along the entire surface of the first side to form an emitter, it is not excluded that such such emitter is applied locally or that a variation in concentration of the emitter is applied along the said surface.

It is furthermore deemed beneficial that metallisation is applied onto the second side, and optionally onto the first side, to create contacts extending into the polysilicon layer without extending into the semiconductor substrate.

The invention furthermore relates to an apparatus for chemical vapour deposition, more particularly an LPCVD apparatus that is provided with a controller, wherein the controller is configured for controlling a deposition process that comprises the deposition of a tunnel dielectric, such as a tunnel oxide, the deposition of a first polysilicon sublayer, optionally in situ doped, the deposition of an intermediate dielectric layer, and the deposition of a second polysilicon sublayer. Such an apparatus is suitable for performing a characteristic portion of the process according to one of the aspects of the invention.

It is observed for clarity that any aspect, embodiment or implementation presented in this application in the figure description, in the claims or in the general description may be applied to any of the disclosed aspects, be it a method or a solar cell, even when this has not been made explicit.

### BRIEF DESCRIPTION OF FIGURES

These and other aspects of the invention will be further elucidated with reference to the Figures that are not drawn to scale and wherein equal reference numerals refer to equal or corresponding parts, wherein:

FIG. 1 diagrammatically shows a solar cell according to a first embodiment in a cross-sectional view;

FIG. 2 schematically shows a process diagram for a first embodiment of the method;

FIG. 3a-3d diagrammatically shows several stages of the first embodiment of the method corresponding to the process diagram shown in FIG. 2;

FIG. 4 schematically shows a further process diagram for a further embodiment of the method;

FIG. 5a-5e diagrammatically shows several stages of the further embodiment of the method corresponding to the process diagram shown in FIG. 4;

FIG. 6 shows a graph of the doping profile of the p-type doped polysilicon layer obtained in the method of the invention;

FIG. 7 shows a graph of the doping profile of a n-doped polysilicon layer obtainable with the method of the invention on the second side of the substrate.

FIG. 8 shows a graph of the lifetime of charge carriers as a function of the injection level for a solar cell of the invention and a comparative solar cell provided with a passivation comprising merely a thermal oxide layer.

### DESCRIPTION OF ILLUSTRATED EMBODIMENTS

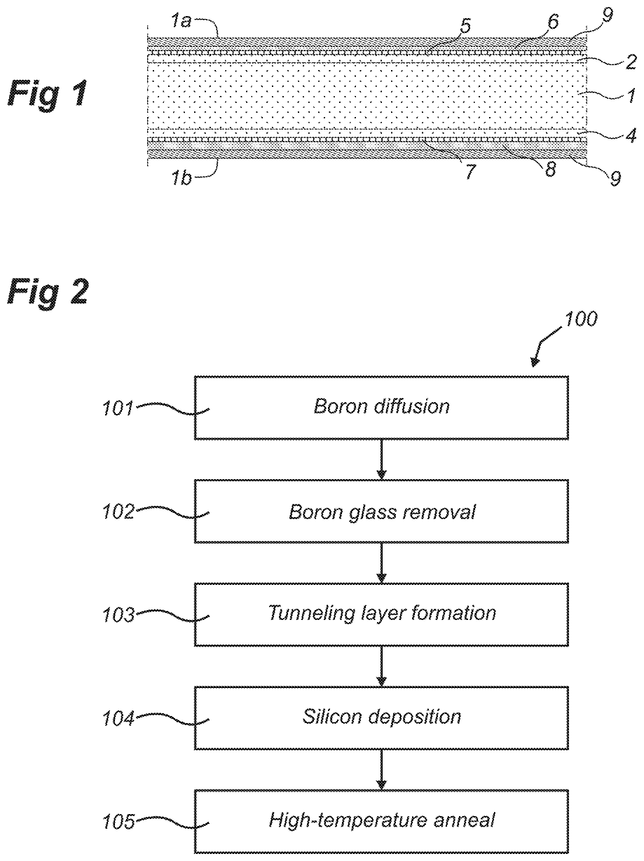

FIG. 1 shows in a diagrammatical, cross-sectional view the solar cell according to a first embodiment of the invention. Like any other figure, this figure is not drawn to scale. The solar cell is provided with a semiconductor substrate 1 having a first side 1a and a second side 1b. While not shown, the semiconductor substrate 1 is preferably provided with a textured surface at the first side 1a. Such a textured surface may be prepared in a manner known to the skilled person. The semiconductor substrate 1 is preferably n-type doped, such as with phosphorous, as known to the skilled person. The semiconductor substrate is particularly a silicon substrate and more particularly a monocrystalline semiconductor substrate. However, any other type of (silicon) substrate is not excluded. In the context of this application, the second side 1b is foreseen to be assembled to a carrier, while the first side 1a is the main side for capturing light, including any radiation outside the visible spectrum, such as UV. However, it is not excluded that light also enters the solar cell from the second side 1b.

At the first side 1a of the substrate 1, an electrically conductive region 2 is provided into the substrate. This electrically conductive region 2 functions as an emitter in the solar cell and is provided with p-type doping, more particularly with boron atoms. At the second side 1b a further conductive region 4 is provided. The presence hereof is not deemed necessary but it can improve the fill factor by enhancing conductivity.

A first passivation comprising a tunnelling dielectric 5 and a polysilicon layer 6 are present on the first side 1a. The tunnelling dielectric 5 is a tunnel oxide in the preferred example, and is provided in a thickness of up to 5 nm, preferably up to 3 nm, more preferably in the range of 1-2 nm. The polysilicon layer 6 may be present in a thickness of 3-50 nm, suitably 5-40 mu, for instance 10-30 nm. Both the tunnel oxide 5 and the polysilicon layer 6 are deposited by means of low pressure chemical vapour deposition in this preferred embodiment. The deposition temperature of the polysilicon temperature may be tuned so as to obtain a desired grain size and extent of crystallinity. Rather than fully polycrystalline the polysilicon layer 6 may be a mixture of a amorphous and a polycrystalline layer upon growth. Subsequent to growth, the polysilicon layer 6 is subjected to a heat treatment in which the polysilicon layer is doped by autodoping from the electrically conductive region 2 with boron dopant atoms. During the heat treatment the crystallinity will increase.

A further passivation comprising a tunnel oxide 7 and a polysilicon layer 8 are present on the second side 1b. In the shown embodiment, the polysilicon layer 8 on the second side 1b has a larger thickness than the polysilicon layer 6 in the passivation on the first side 1a. In accordance with one aspect of the invention, the polysilicon is initially applied in the thickness for the second side 1b and then etched back from the first side 1a up to an etch stop interface, such as an intermediate dielectric in the polysilicon layer 8 (not shown in the figures). Selective etching of the polysilicon layer 6 on the first side 1a relative to that on the second side 1b may be achieved in various ways, preferably using an etch resistance enhancement treatment on the second side 1b, for instance in the form of amorphisation of at least a top portion of the polysilicon layer 8 on the second side 1b, and/or by application of a mask layer.

In the illustrated embodiment, the polysilicon layers 6, 8 on the first side 1a and on the second side 1b are each covered by a nitride layer 9. The nitride layer 9 is more particularly a silicon nitride layer, but can in one embodiment also be a silicon oxynitride layer or a stack of layers among which one or more are formed of silicon nitride. The nitride layer 9 is more particularly a hydrogenated silicon nitride layer, also known as SiNx:H. The hydrogen however is made to migrate at least partially to the underlying polysilicon layers 6,8. While not shown in this FIG. 1, the polysilicon layer 8 on the second side 1b may include an intermediate layer different from n-type doped polysilicon. For instance, such intermediate layer may be an oxide layer. It is particularly present in a small thickness of for instance less than 3 nm, more preferably less than 2 nm or even less than 1 nm. The intermediate oxide layer would more particularly be an intermediate thermal oxide layer that is formed in the same reactor as the polysilicon layers 6, 8.

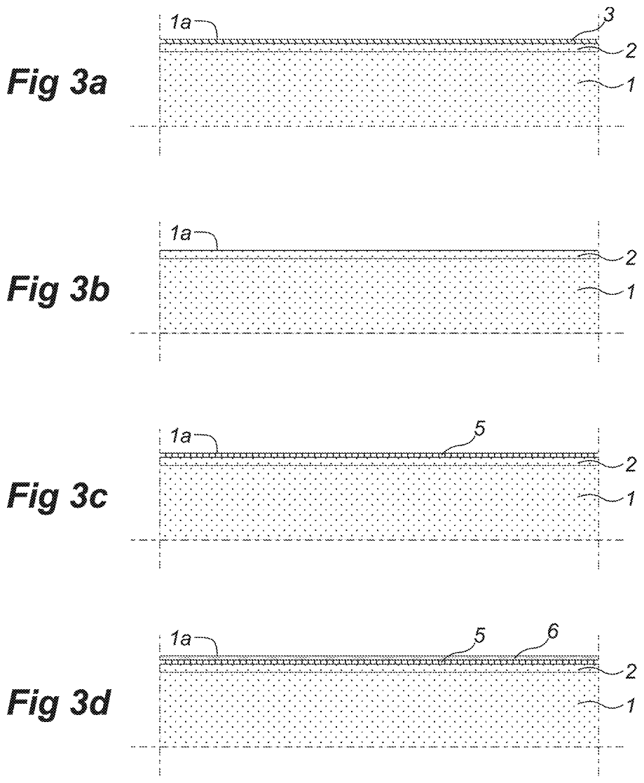

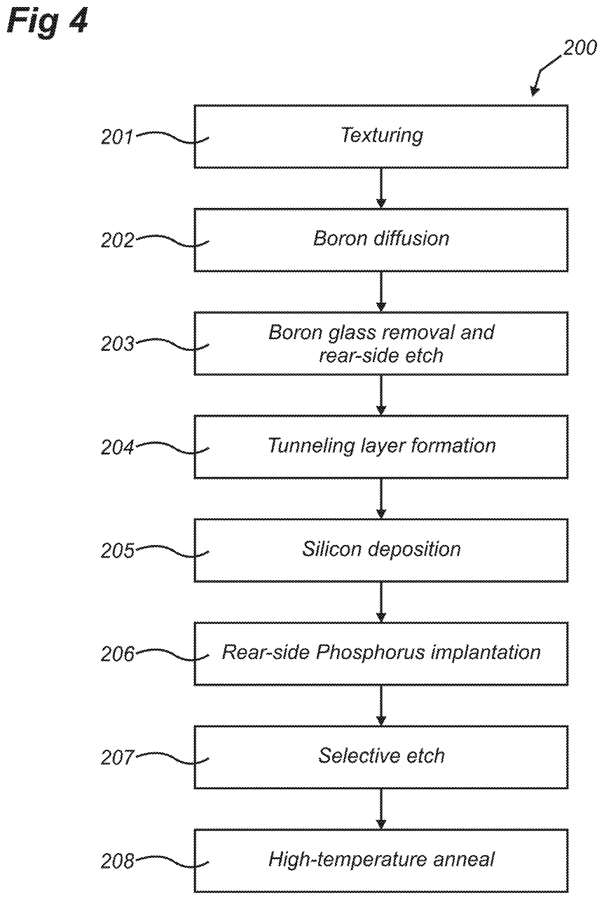

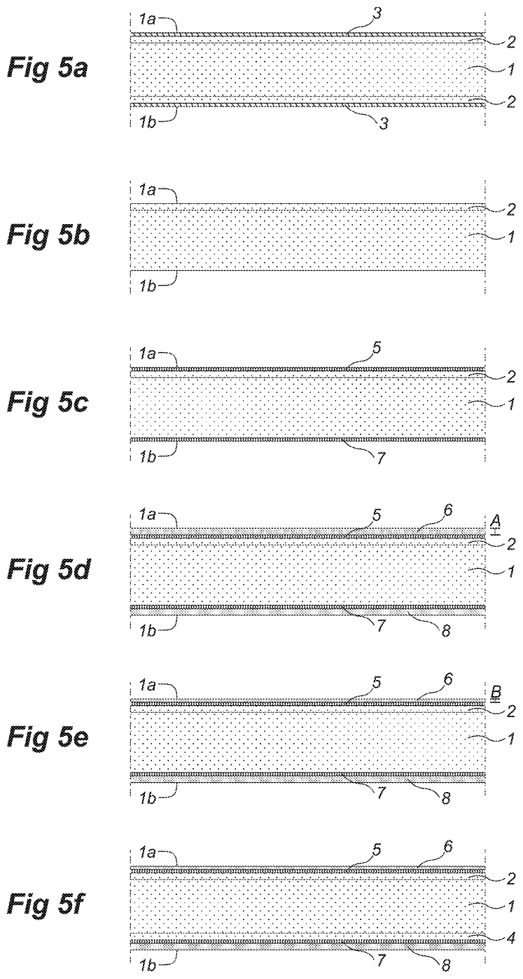

FIG. 2 diagrammatically indicates the basic steps for the generation of the improved passivation on the first side 1a in accordance with the invention. The steps in FIG. 2 correspond with the stages in the manufacture as shown in FIG. 3a-3d. While FIG. 3a-d show single-sided development of an electrically conductive region 2, a tunnel dielectric 5 and a polysilicon layer 6, it is observed that two-sided formation is not excluded and even common. One embodiment of such two-sided processing will be discussed with reference to the process flow of FIG. 4 and the cross-sectional views shown in FIG. 5a-e.

As shown in step 101, the process starts with diffusion of boron dopant atoms into the substrate 1. The diffusion is carried out by the application of a dopant layer 3 followed by a heat treatment for the actual diffusion from the dopant layer 3 into the substrate 1 to define an electrically conductive region 2. As known to the skilled person, a common way of applying the dopant layer 3 is the provision of a gaseous dopant source such as BBr3 in an oxygen containing atmosphere. The boron source reacts with the silicon substrate to form a borosilicate glass layer. After the heat treatment, the dopant concentration at the first side 1a of the substrate 1 is for instance in the range of 4-10.10¹⁹/cm³.

FIG. 3b shows the result of a second step 102 in the process, which is the removal of the dopant layer 3 of borosilicate glass—also referred to as boron glass. Use is made of a conventional etch as known to the skilled person.

FIG. 3c shows the result of a third step 103 in the process, which is the formation of a tunnel dielectric 5, more particularly a tunnel oxide 5. The tunnel dielectric is grown in a Chemical Vapour Deposition (CVD) reactor as a thermal oxide. It has been found by the inventors in preliminary investigations, that the behaviour of a thermal oxide is significantly different, with respect to diffusion, to a wet-chemically deposited oxide. Preferably, the thermal oxide has a thickness of less than 5 nm, more preferably up to 3 nm. The thermal oxide is in an even more preferred embodiment formed in a Low-Pressure Chemical Vapour Deposition (LPCVD) reactor, for instance of the horizontal type. Such a growth process has the advantage that the thermal oxide is formed in a conformal manner on the underlying substrate, that is provided with a textured surface. More importantly, by growth in an LPCVD reactor, it is feasible to carry out the growth of the tunnel oxide and the subsequent deposition of the polysilicon layer in the same reaction chamber. This is beneficial to minimize contamination of the thermal oxide and to reduce stress development in the substrate, as there is no need of cooling down to room temperature to expose the fresh tunnel oxide to an atmosphere outside the LPCVD reactor.

In the fourth step 104 of which the result is diagrammatically shown in FIG. 2d, a polysilicon layer 6 is deposited. The deposition of the polysilicon layer 6 preferably is done in an LPCVD reactor, more particularly at a temperature between 500 and 700° C. It is deemed feasible that this polysilicon layer 6 is in situ doped with a gaseous source of dopant, as known per se to the skilled person. The thickness of the polysilicon layer 6 is suitably less than 30 nm, preferably less than 20 nm. This thickness may be achieved either by means of the deposition time or through a combination of deposition to a larger thickness and subsequent etching.

In the fifth step 105, the polysilicon layer 6 is subjected to a high temperature anneal. The term ‘high temperature’ is understood in the context of the present invention, as a temperature and duration that is sufficient to cause migration of boron atoms. Preferably, the temperature of the anneal is at least 900° C., and the duration is at least 10 minutes and more preferably at least 30 minutes. As a consequence of the boron migration, the high-temperature and the small thickness of the polysilicon layer, it is believed that the crystallinity of the polysilicon layer significantly enhances. This is beneficial for the optical transmission of light through the polysilicon layer 6 into the substrate 1.

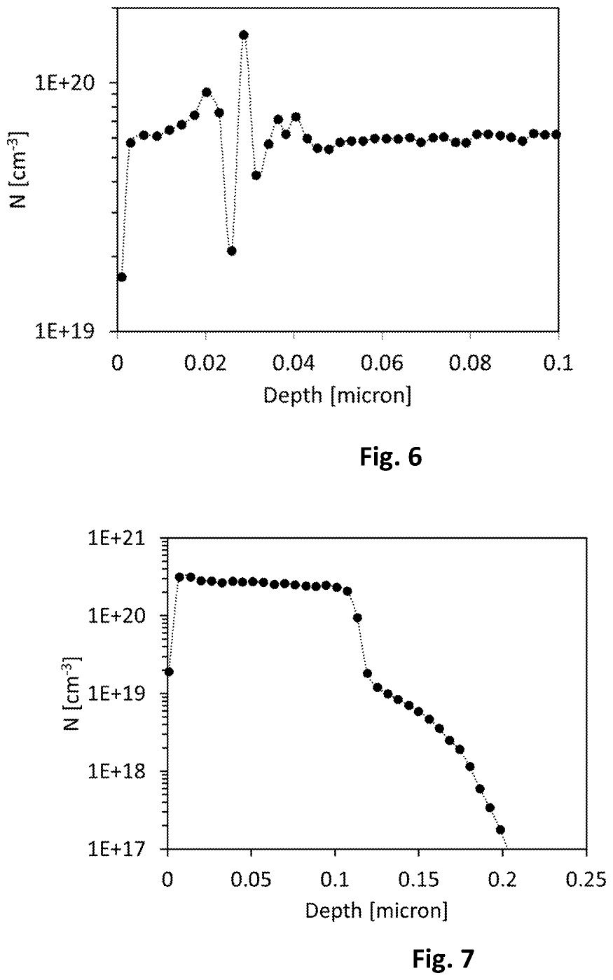

FIG. 6 shows a diagram in which the boron dopant concentration is shown for a layer portion of 100 nm (0.1 micron) starting at the surface of the substrate. The dopant concentration was determined by means of an ECV measurement as known per se. The sample was prepared in accordance with the method shown in FIG. 1, wherein a boron dopant was applied in the semiconductor substrate 1 both at the first side 1a and the second side 1b to form an emitter. The semiconductor substrate 1 was a monocrystalline silicon substrate formed by the Czochralski-method as commercially available for solar cells. This is also the preferred type of semiconductor substrate in the invention. The substrate was n-type doped. It was provided with textured surfaces on the first side and on the second side. Use was made of a BBr3, that formed borosilicate glass on the silicon substrate. After an anneal to diffuse the boron into the silicon substrate, the borosilicate glass was removed. Thereafter, a tunnel oxide 5 and a polysilicon layer 6 were applied both on the first side 1a and on the second side 1b, by means of LPCVD in a horizontal furnace supplied by Tempress Systems B.V. An anneal was carried out so as to diffuse the boron dopant from the electrically conductive region in the substrate to the polysilicon layer 6. Finally, hydrogenated silicon nitride layers were applied at the first and the second side at 300-600° C.

In the resulting ECV measurement, it is clearly visible that the boron concentration in the first 20-25 nm tends to be higher than the concentration in the substrate, of about 5.10¹⁹/cm³. At 25 nm, a minimum in the concentration is found, which is deemed to correspond to the presence of the tunnel oxide. Beyond that, the boron concentration at the interface of the tunnel oxide and the substrate is again enhanced. From several measurements it appears that the measurement of the doping profile at the interface between the polysilicon layer and the substrate appears subject to noise. No clear meaning can therefore be given to the peak at about 30 nm. This FIG. 6 demonstrates the formation of a doped boron polysilicon layer. It is seen that the polysilicon is doped to a high level, similar to the boron concentration in the emitter. Since all the boron atoms have to penetrate the silicon oxide one would not expect the silicon oxide to still be a good passivation layer.

In comparative examples of ECV measurements without a polysilicon layer, the dopant concentration is substantially uniform throughout the 100 nm, and roughly between 4 and 5.10¹⁹/cm³. Merely close to the substrate surface, a lower concentration is visible, which corresponds to the presence of a—native—silicon oxide layer.

For sake of reference, FIG. 7 shows a graph of an ECV measurement on a polysilicon layer that has been doped with an n-type dopant, more particularly phosphorus. The sample was prepared by the provision of boron dopant into the first side and the second side of a monocrystalline silicon substrate for solar cells. Use was made of BBr3 as a dopant, which was provided by chemical vapour deposition and formed borosilicate glass. A heat treatment was carried out to diffuse the boron from the borosilicate glass into the silicon substrate in known manner. The substrate had been provided with a textured surface using an alkaline etch with KOH as known per se, prior to the application of a boron dopant source. After the diffusion, the boronsilicate glass was removed from the first side and the second side. Moreover, the formed conductive region on the second side was also removed by etching.

Thereafter, a tunnel oxide and polysilicon were applied both on the first side and the second side in a LPCVD reactor as commercially available from Tempress Systems in exactly the same manner as indicated above with reference to FIG. 6. The polysilicon was deposited without doping. Subsequently, the polysilicon on the second side was doped by implantation using phosphorus. Herein, the polysilicon on the second side was made amorphous. This enabled selective removal of the polysilicon on the first side up to the tunnel oxide. This was followed by an anneal to distribute the implanted phosphorus through the polysilicon layer on the second side, and to recrystallize the amorphized silicon into polysilicon. Hydrogenated silicon nitride layers were deposited on the first and the second side using a PECVD reactor of Tempress Systems By. A firing step at 800° C. was applied to achieve hydrogen migration from the silicon nitride into the polysilicon.

As shown in FIG. 7, the dopant concentration in the polysilicon is above 2.10²⁰/cm³. However, even with such high dopant concentration, the amount of dopant introduced into the underlying silicon substrate is significantly lower. The concentration ratio at opposite sides of the tunnel oxide (close to 0.1 micron) is 10. At a depth of 200 nm, which is 100 nm below the tunnel oxide, the substrate concentration is down to 1.10¹⁷/cm³ which is more than a factor of 1000 below the concentration in the polysilicon layer. Hence, it is found that while boron diffuses back into the polysilicon layer to a concentration equal or higher than in the substrate, the phosphorus does not migrate through the tunnel oxide to a substantial extent. This indicates the surprising character of the boron migration through the tunnel oxide into the polysilicon layer.

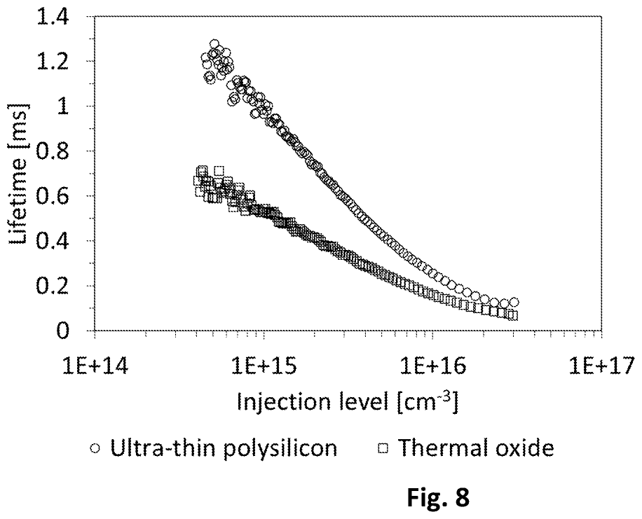

FIG. 8 shows further measurement results based on the samples made as discussed with reference to FIG. 7. The measurement results is a QSSPC lifetime measurement. Use was made of a Sinton WCT-120 wafer measurement instrument, as commercially available, in the manner known per se to the skilled person, i.e. using a series of injection levels. The measured lifetime herein refers to the lifetime of charge carriers. The longer the lifetime, the longer it takes before recombination of charge carriers occurs. The longer the recombination time, the lower the risk of surface recombination, which reduces the effective efficiency of the solar cell to convert light and other radiation into electricity.

The lifetime measurements were carried out for two samples prepared in accordance with the method identified with reference to FIG. 7, with as prime difference the etching time of the polysilicon on the first side, after the implantation step. In the sample according to the invention, the polysilicon layer on the first side was thinned back. In the comparative sample, the polysilicon layer on the first side was removed entirely. As a consequence, nothing but a tunnel oxide in the form of a thermal oxide remained below the hydrogenated silicon nitride layer.

As shown in FIG. 8, the charge carrier lifetime for the solar cell in accordance with the invention is significantly higher than for a comparative solar cell without the thinned polysilicon layer, which was—as demonstrated in FIG. 6—doped with boron dopant from the conductive region in the substrate. The increase of the average lifetime is from 0.5 ms to 0.9-1.0 ms. On the basis of these lifetime measurements an implied open-circuit voltage V_{oc} was calculated. This was 12 mV higher for the solar cell of the invention than for the reference solar cell. This demonstrates the improved passivation of the solar cell of the present invention.

FIG. 4 shows a process flow for a process according to a second embodiment of the invention. This embodiment involves double sided processing of a semiconductor substrate, which is more particularly a silicon substrate. The substrate 1 is provided with a first side 1a and an opposed second side 1b. The first main step 201 in the process is the provision of a textured surface on the first side 1a of the substrate 1. Typically, use is made of an alkaline etch. It is possible but not necessary that the second side 1b is provided with a textured surface as well.

As a second step 202, a boron diffusion is applied into the substrate, resulting in a dopant layer 3, typically a boron glass, and an electrically conductive region 2. As is shown in FIG. 5a, the dopant layer 3 and the electrically conductive region 2 are provided both on the first side 1a and on the second side 1b. This double-sided processing is based on the provision of the dopant layer by means of vapour deposition of a dopant source. It is not excluded that an alternative method for the provision of the dopant layer is used, which can be applied in a single-sided manner.

As a third step 203, of which the result is shown in FIG. 5b, the dopant layer 3 is removed from both the first side 1a and the second side 1b of the substrate 1, and the electrically conductive region 2 is removed from the second side 1b, by means of single-sided etching of the substrate 1 from the second side 1b.

In a fourth step 204, a tunnel dielectric 5 is applied, as shown in FIG. 5c. In a fifth step, a polysilicon layer 6 is applied on the tunnel dielectric 5, of which the result is shown in FIG. 5d.

These steps are suitably carried out in the manner as discussed with reference to FIGS. 3c and 3d, with the exception that both layers are deposited both on the first side 1a and on the second side 1b. In the preferred implementation of this second embodiment, the polysilicon layer 6, 8 is provided in an initial thickness A of 50-200 nm. In one implementation, the polysilicon layer 6,8 is in situ doped. In another implementation, the polysilicon layer 8 is doped after deposition, and more preferably selectively at the second side 1b, for instance by means of ion implantation using directional ion beams. In again a further implementation, a combination of both doping methods is applied. The doping of the polysilicon layer 8 on the second side with phosphorous is shown as a sixth step 206 in FIG. 4.

In a seventh step 207, of which the result is shown in FIG. 5e, the polysilicon layer 6 on the first side 1a is selectively etched back, so as to obtain a reduced thickness B, particularly of less than 30 nm and more preferably of less than 20 nm, for instance 5-15 nm. The etching may be carried out by temporarily protecting the second side with a masking layer (not shown), which is resistant to an etchant for polysilicon. A suitable etch is for instance an alkaline etch. The etching could further be carried out by means of applying the etch selectively on the first side 1a, while the substrate 1 lies on a carrier with its second side 1b, or in a manner that the etch is merely applied on the first side, such as by printing or coating an etch or etch paste, that after heating or irradiating may etch the underlying polysilicon layer 6. In a preferred embodiment, however the etching is selective in that an etching resistance enhancement treatment is applied out on the polysilicon layer 8 on the second side 1b of the substrate 1. One preferred embodiment of this etching resistance enhancement treatment is implantation with an implantation dose that results in amorphisation of the polysilicon layer, or at least a top surface thereof. Then, no separate masking layer is needed.

In a preferred implementation, an intermediate layer is present within the polysilicon layers 6, 8. This intermediate layer is used as an etch stop during etching of the polysilicon layer 6 on the first side. This intermediate layer is however not blocking diffusion of dopant through the polysilicon layer 8 on the second side 1b. An example of a suitable intermediate layer is for instance a silicon oxide layer, a silicon oxynitride or a silicon nitride layer. Preferably, the intermediate layer is sufficiently thin, for instance less than 3 nm. More preferably, the intermediate layer is deposited in the same reactor as the polysilicon layers 6,8, thus particularly in an LPCVD reactor.

In an eighth step 208, the substrate with the polysilicon layers 6, 8 of different thickness is thereafter annealed. More particularly, the anneal is carried out such to diffuse boron dopant present in the substrate 1 at the first side 1a in the electrically conductive region 2, that is foreseen to act as an emitter, to migrate through the tunnel oxide 5 into the polysilicon layer 6. In one implementation, the anneal temperature is at least 900° C., for instance 950-1000° C., and the duration of the anneal is at least 10 minutes, preferably at least 30 minutes, for instance 30-60 minutes. As a result of this high-temperature anneal, the dopant atoms in the polysilicon layers 8 are spread through this layer 8 to obtain a doping with a substantially uniform dopant concentration. Furthermore, dopant atoms from the electrically conductive region migrate into the polysilicon layer 6. Additionally, the polysilicon layer 6 is crystallized under the increased temperature, in the sense that the average grain size of the polycrystallites grows. It is believed by the inventors that the limited thickness of the polysilicon layer 6 contributes to the growth of the crystallinity, in the sense that the growth direction will be primarily lateral. It is moreover not excluded that boron doping further contributes to growth of the crystallinity. As shown in FIG. 5f, the phosphorus doping may herein form a back surface field layer 4 in the substrate 1.

In a ninth step, a silicon nitride layer is deposited. Preferably, as shown in FIG. 1, the silicon nitride layer is deposited both on the first side 1a and on the second side 1b. The silicon nitride is more particularly deposited as a hydrogenated silicon nitride SiNx:H, and the deposition is carried out at such a temperature that migration of hydrogen into the polysilicon layer and optionally to the tunnel oxide occurs. Alternatively, such migration is effected by a heat treatment after deposition, for instance in the temperature range of 400-800° C. It is believed that the hydrogen migration has a beneficial effect on the passivation properties, particularly in relation to the structure and quality of the tunnel oxide.

Thus, in accordance with one aspect of the invention, a passivated solar cell is manufactured in a method comprises the steps of: (1) providing an electrically conductive region at a first side of a semiconductor substrate provided with a textured surface, which comprises dopant atoms of p-type conductivity, and particularly boron; (2) providing a passivation by applying a tunnelling dielectric layer and a polysilicon layer and carrying out an anneal so as to diffuse dopant atoms from the electrically conductive region into the polysilicon layer. A hydrogenated silicon nitride or silicon oxynitride layer may be present on top of the polysilicon layer. The resulting solar cell has a significantly increased lifetime of charge carriers and therewith enhanced open-circuit voltage.

In accordance with another aspect, a solar cell is provided comprising a semiconductor substrate having a first side and an opposed second side, on which first side and which second side a tunnelling dielectric and a polysilicon layer are present, wherein at least the polysilicon layer on the second side is at least partially doped with n-type dopant, wherein the polysilicon layer on the second side has a larger thickness than the polysilicon layer on the first side; wherein the polysilicon layer on the second side comprises a first and a second sublayer of polysilicon, and any remainder of an etch stop interface between them. In one preferred embodiment, the etch stop interface is an intermediate layer of dielectric material between the first sublayer and the second sublayer. Preferably, contacts on the second side extend into the polysilicon layer without extending into the semiconductor substrate, and wherein an antireflection coating overlies the polysilicon layer on the first side.

In accordance with a further aspect, a passivated solar cell is manufactured in a process comprising:
providing a semiconductor substrate with a first and a second opposed side;
providing a tunnel dielectric and a polysilicon layer onto the first side;
providing a tunnel dielectric and a polysilicon layer onto the second side;

Wherein
the tunnel dielectrics and the polysilicon layers on the first and the second side are simultaneously formed;
an etch stop interface is created within the polysilicon layer on the first side;
the polysilicon layer on the first side is thinned up to the etch stop interface.

Preferably, the method further comprises
applying a dopant to the polysilicon layer on the second side;
diffusing the dopant into the polysilicon layer on the second side by means of an appeal, and
providing an antireflection coating on the first side;

1. A method of manufacturing a passivated solar cell, comprising the steps of:
providing an electrically conductive region at a first side of a semiconductor substrate;
providing a passivation on the first side,
wherein:
the electrically conductive region comprises dopant atoms of p-type conductivity,
the passivation is provided by applying a tunnelling dielectric layer and a polysilicon layer and carrying out an anneal so as to diffuse dopant atoms from the electrically conductive region into the polysilicon layer.

2. The method as claimed in claim 1, wherein a hydrogenated nitride or oxynitride is applied on the polysilicon layer.

3. The method as claimed in claim 1, wherein the tunnelling dielectric layer is a tunnel oxide that is applied by thermal oxidation.

4. The method as claimed in claim 1, wherein the electrically conductive region is applied by diffusion of boron into the semiconductor substrate using a heat treatment.

5. The method as claimed in claim 1, wherein the tunnelling dielectric and the polysilicon layer are applied on the first side and on an opposed second side.

6. The method as claimed in claim 5, wherein the polysilicon layer of the first side is thinned back prior to the anneal step, so that the polysilicon layer on the first side is thinner than the polysilicon layer on the second side.

7. The method as claimed in claim 5, wherein the polysilicon layer on the second side is doped with dopant atoms of n-type conductivity.

8. The method as claimed in claim 1, wherein the polysilicon layer is provided with an etch stop interface, and wherein the polysilicon layer of the passivation is thinned back up to the etch stop interface.

9. The method as claimed in claim 6, wherein n-type doping of the polysilicon layer is applied during the deposition of the polysilicon layers, such that a first sublayer of the polysilicon layer has a lower concentration of n-type doping than a second sublayer, and wherein said second sublayer is removed from the first side after the deposition.

10. The method as claimed in claim 6, wherein the polysilicon layer is doped at the second side after its deposition by means of ion implantation.

11. The method as claimed in claim 6, wherein the polysilicon layer on the first side is thinned back to a thickness of at most 50 nm.

12. The method as claimed in claim 1, wherein at least one contact is applied into the polysilicon layer without extending into the semiconductor substrate.

13. (canceled)

14. The method as claimed in claim 1, wherein the dopant concentration of p-type dopant in the polysilicon layer on the first side is in the range of less 10¹⁹-10²⁰/cm³.

15-18. (canceled)

19. The method as claimed in claim 9, wherein the first sublayer of the polysilicon layer is applied substantially without doping, or alternatively wherein the first sublayer is doped during its application with p-type dopant.

20. The method as claimed in claim 1, wherein the first side is provided with a textured surface.

21. A method of manufacturing a solar cell with at least one passivated contact, comprising the steps of:
providing an electrically conductive region at a first side of a semiconductor substrate, which electrically conductive region is provided with dopant atoms of p-type conductivity,
applying a tunnelling dielectric layer;
applying a polysilicon layer, and
carrying out an anneal so as to diffuse dopant atoms from the electrically conductive region into the polysilicon layer.

22. The method as claimed in claim 21, wherein at least one contact is applied into the polysilicon layer without extending into the semiconductor substrate.

23. The method as claimed in claim 21, wherein a contact area is defined in the polysilicon layer, in that at least part of the polysilicon layer outside said contact area is thinned back or entirely removed.

24. The method as claimed in claim 21, wherein further comprising the steps prior to carrying out the anneal:
defining at least one first area and at least one second area in the polysilicon layer;
applying dopant atoms of n-type conductivity in the at least one second area of the polysilicon layer;
thinning back the at least one first area of the polysilicon layer;
applying contacts to the said first area and second area,
wherein the anneal is carried out to diffuse the p-type dopant atoms into the polysilicon layer and to distribute the n-type dopant through the at least one second area.

25. A method of manufacturing a solar cell with at least one passivated contact, comprising the steps of:
providing an electrically conductive region at a first side of a semiconductor substrate, which electrically conductive region is provided with dopant atoms of p-type conductivity,
applying a tunnelling dielectric layer;
applying a polysilicon layer, said polysilicon layer comprising a mixture of amorphous and polycrystalline silicon, and
carrying out an anneal so as to diffuse dopant atoms from the electrically conductive region into the polysilicon layer, wherein the anneal enhances the crystallinity of the polysilicon layer.
